(19) United States
(12) Patent Application Publication
(10) Pub. No.: US 2026/0298981 A1
(43) Pub. Date: Oct. 1, 2026

(54) MEMS PROBE NEEDLE STRUCTURE AND RELATED METHODS

(71) Applicant: Taiwan Semiconductor Manufacturing Company Limited, Hsin-Chu (TW)

(72) Inventors: Guang-Sing HUANG, Hsinchu County (TW); Kai-Yi TANG, New Taipei City (TW); Chuei-Tang WANG, Taichung City (TW); Kuan Chun CHEN, Hsinchu City (TW)

(21) Appl. No.: 19/095,128

(22) Filed: Mar. 31, 2025

(51) Int. Cl. G01R 1/067; G01R 1/073; G01R 3/00

(52) U.S. Cl. CPC G01R 1/06761; G01R 1/0675; G01R 1/07342; G01R 3/00

(57) ABSTRACT

A method is provided. The method includes: extending a first probe needle of a probe card assembly to contact a first electrical bump of an integrated circuit (IC) die, the first probe needle including: a first crystalline layer extending from a first end of the first probe needle to a second end of the first probe needle, the first crystalline layer having a first resistivity; and a second crystalline layer extending from the first end to the second end and positioned adjacent the first crystalline layer, the second crystalline layer having crystalline structure that is different than that of the first crystalline layer and having a second resistivity that is less than the first resistivity. The method includes: extending a second probe needle of the probe card assembly to contact a second electrical bump of the IC die; and performing an electrical test on the IC die by a test head in electrical communication with the probe card assembly, including: transmitting a test signal from the test head to the first electrical bump via the first probe needle; and receiving a response signal associated with the test signal from the second electrical bump via the second probe needle.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagrammatic view of a wafer test system, in accordance with some embodiments.

FIG. 2A illustrates a partial diagrammatic view of a wafer test system, in accordance with some embodiments.

FIG. 2B illustrates a partial diagrammatic view of a wafer test system, in accordance with some embodiments.

FIG. 3A illustrates a diagrammatic view of a probe needle, in accordance with some embodiments.

FIG. 3B illustrates a diagrammatic view of a probe needle, in accordance with some embodiments.

FIG. 3C illustrates a diagrammatic view of a probe needle, in accordance with some embodiments.

FIG. 3D illustrates a diagrammatic view of a probe needle, in accordance with some embodiments.

FIGS. 4A, 4B, 4C, 4D, 4E, 4F, 4G, 4H, 4I, and 4J are diagrammatic views of a method of forming a probe needle, in accordance with some embodiments.

FIG. 5 is a flow diagram illustrating a method, in accordance with some embodiments.

FIG. 6 is a flow diagram illustrating a method, in accordance with some embodiments.

FIG. 7 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, a testing probe or “probe needle” is a component of a test system that contacts a device or “device under test” (DUT) and a selected printed circuit board (PCB) probe card or multilayer organic (MLO) substrate to determine functional validity of one or more circuits of the DUT. As feature dimensions shrink and operating voltages are reduced, high probe needle impedance and poor contact reliability can result from high resistance of a tip thereof and an amorphous structure of a body thereof. Due to the amorphous structure of the body, current conducted by the probe needle passes through amorphous boundaries that have high resistance, which results in a high voltage drop that reduces total probe card system power integrity performance. Increased probe needle resistance can result in reduced performance, such as increased direct current (DC) resistance and/or increased alternating current loss (ACL). Increased probe needle resistance can also result in the body of the probe needle being prone to accumulate heat (e.g., Joule's law), which can result in a tip of the probe needle being burnt. The amorphous structure can result in deformation of the tip, which shortens lifetime of the probe needle, leading to frequent probe needle replacement and/or repair, reducing wafer-per-hour (WPH) throughput of the test system.

In embodiments of the disclosure, a multilayer probe needle includes a first layer that has relatively high hardness and high electrical resistivity, and a second layer that has relatively low hardness and low electrical resistivity. Each of the first layer and the second layer has substantially uniform crystalline structure, respectively. As a result, testing interface resistance is reduced due to a super lattice structure that increases freedom of electron motion and improves speed and efficiency of electron transmission. The multilayer probe needles have improved band energy structure resulting from the super lattice structure having band structure of materials (or “band gap tuning”) selected to be suitable for a target DUT or test profile. The multilayer probe needles have improved material stability and durability resulting from the super lattice structure having structure that can reduce defects and impurities in the materials of the first layer(s) and the second layer(s). The multilayer probe needles have reduced electrical loss, which can improve yield performance. The multilayer probe needles can have reduced heat accumulation in a body thereof, resulting in mitigation of burning at the tip or “end” thereof. The “tip” can refer to an end of the probe needle that is operable to contact the DUT.

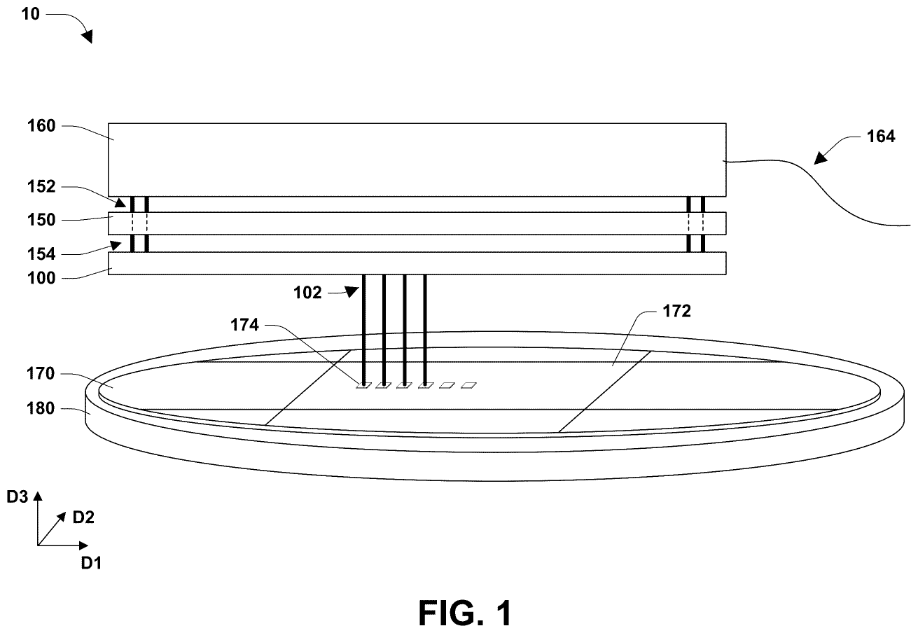

FIG. 1 illustrates a test apparatus 10 that is operable to perform an electrical test on an in-process integrated circuit (IC) wafer 170, according to some embodiments.

The in-process IC wafer (or simply “the wafer”) 170 can include at least two integrated circuit die regions 172 positioned therein, each of which may be referred to as a DUT 172.

In some embodiments, a semiconductor substrate of the wafer 170 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor substrate comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate are within the scope of the present disclosure.

In some embodiments, the IC die regions 172 can be in-process dies or completed dies that are to be singulated in a subsequent process operation. The IC die regions 172 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs, and the like. In some embodiments, the IC die regions 172 can include interconnect bumps or “pads” 174 that are associated with electronic circuits. For example, the interconnect bumps 174 can be in electrical contact with interconnect circuitry of the electronic circuits. In some embodiments, the IC die regions 172 are arranged in one or more rows and one or more columns. The rows extend along a first direction and are arranged along a second direction. The columns extend along the second direction and are arranged along the first direction.

In some embodiments, each of the IC die regions 172 includes one or more patterned layers of different materials that are arranged to form electronic circuits. Components of each IC die region 172 can include transistors, interconnects, capacitors, resistors, inductors and the like. The IC die region 172 can include many material layers, such as the substrate, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching, doping, planarization, and the like. Along a vertical axis that is perpendicular to the major surface of the IC die region 172, from bottom to top, the IC die region 172 can include a device region and an interconnect region on the device region. The device region can generally include the transistors and capacitors, and the interconnect region can generally include the interconnects, capacitors, inductors, resistors, and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

The wafer 170 may be positioned on a wafer stage 180 of the test apparatus 10, which can include one or more of a wafer chuck that secures and optionally heats or cools the wafer 170, one or more actuators that can translate the wafer 170 in horizontal and vertical directions and an alignment system that can include optical alignment devices (e.g., one or more cameras, microscopes or the like), stepper motors, and the like.

In some embodiments, the test apparatus 10 includes a probe card assembly 100, a test head 160 and an optional interface or “interface board” 150 between the test head 160 and the probe card assembly 100. The test head 160 can be in data communication with a test cabinet via a cable or cable bundle 164.

In operation, a signal path is present that extends from the test cabinet or “tester” to a DUT (e.g., the IC die region 172) of the wafer 170. The test cabinet or tester generates electrical signals that are used to test semiconductor devices of the IC die region 172. This can include control signals, data signals, power, ground, and the like. The electrical signals exit the test cabinet via various connectors, which can include general purpose interface bus (GPIB), universal serial bus (USB), or other suitable high-speed interfaces. The electrical signals travel through a cable(s) 164 beneficial to maintain signal integrity. In some embodiments, the cables 164 can be or include coaxial cables for high-frequency signals, ribbon cables for parallel data, multi-conductor cables for power and control signals, and the like. The electrical signals can initially enter the test head 160, which is an assembly that is positioned between the tester and the probe card assembly 100. Within the test head 160, signal conditioning circuits such as amplifiers, filters, or impedance matching networks can adjust the electrical signals for selected testing recipes, to compensate for cable losses and the like. Then, the electrical signals may be transitioned to first pogo pins 152, which can be spring-loaded pins that provide a flexible electrical connection, compensating for small misalignments. In some embodiments, the interface board 150, which can be referred to as a space transformer, is located within or near the test head 160. The interface board 150 is operable to adapt pitch of connections from the test head 160 to match pitch of the probe card assembly 100, for example, via second pogo pins 154. In some embodiments, the interface board 150 fans out signals to match density and pattern of contacts of the probe card assembly 100, which is beneficial for managing a transition from fewer, larger contact points to many smaller, closely spaced ones. The electrical signals are then passed through the probe card assembly 100, which can include an array of probe needles or micro-spring contacts 102. Each probe needle 102 corresponds to a selected pad 174 or test point on the IC die region 172. The probe needles 102 are positioned precisely to make contact with the pads 174 on the wafer 170. The probe card assembly 100 may be operable to test one or multiple die IC regions 172 at once, depending on a testing strategy. The electrical signals from the tester are applied to the semiconductor devices via the probe needles 102. Input signals can be applied to stimulate the device under test (DUT), and output signals can carry responses from the DUT that are captured back through the same signal path to evaluate performance, functionality, or other metrics of the IC die region(s) 172.

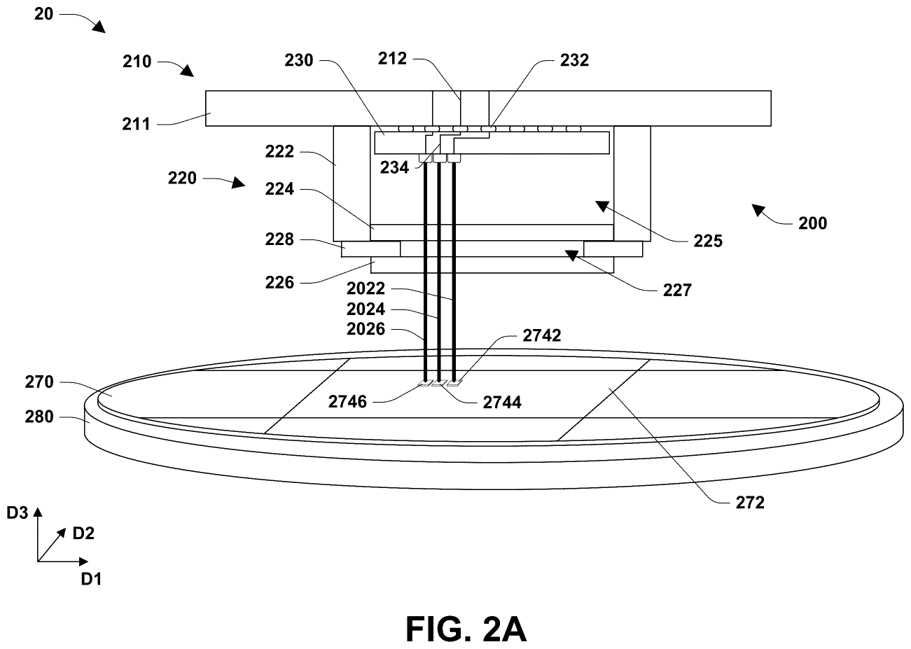

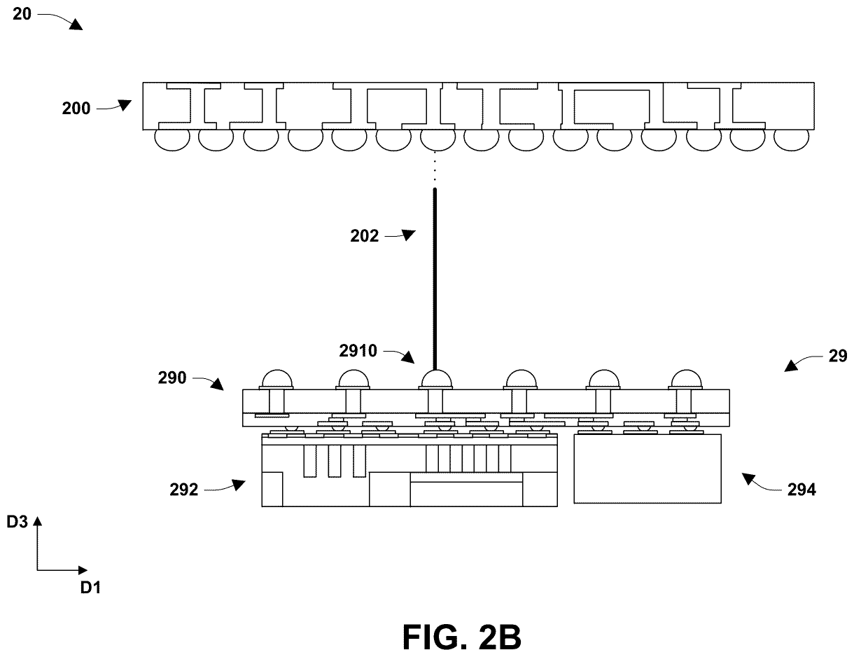

FIGS. 2A and 2B illustrate partial diagrammatic views of a wafer test system 20, in accordance with some embodiments. In FIGS. 2A and 2B, probe card assemblies 200 are illustrated that include a probe card 210, a jig assembly 220 on the probe card 210, and a multilayer organic (MLO) substrate 230 on the probe card 210 in an opening 225 defined by the jig assembly 220. Many elements of the wafer test systems of FIGS. 2A and 2D are similar in most respects to those described with reference to FIG. 1, and can be understood in detail by referring to the description that references FIG. 1.

In FIG. 2A, a wafer 270 may be positioned on a wafer stage 280 of the wafer test system. The wafer 270 and the wafer stage 280 are similar in most respects to the wafer 170 and the wafer stage 180 described with reference to FIG. 1. Major surfaces of the wafer 270 and the IC die region 272 thereof may be oriented in a horizontal plane that includes a first direction D1 and a second direction D2 that are transverse (e.g., perpendicular) each other. A third direction D3 or “vertical direction” may be perpendicular to the horizontal plane.

The probe card assembly 200 is positioned above the wafer 270 and the wafer stage 280 in the third direction D3, and is operable to perform electrical tests on an integrated circuit (IC) die region 272 of the wafer 270. The IC die region 272 is similar in most respects to, and an embodiment of, the IC die region 172 described with reference to FIG. 1. The probe card assembly 200 includes the probe card 210, the jig assembly 220, and the MLO substrate 230.

The probe card 210 includes first electronic circuits 212 positioned in a substrate 211. The first electronic circuits 212 are electrically connected to probe needles 2022, 2024, 2026. In some embodiments, the substrate 211 can be or include a printed circuit board (PCB) having at least two layers. The PCB can be or include a multi-layer printed circuit board that has high-density interconnects (HDI). The PCB can include materials, such as FR-4 (“Flame Retardant 4”), polyimide or BT resin, with multiple routing layers to provide complex signal paths. The PCB can include via structures for vertical interconnects, which can include micro-vias for finer pitch, and may include openings therein for mounting the probe needles 2022, 2024, 2026 through drilled holes or as part of an integrated probe array.

In some embodiments, the first electronic circuits 212 include one or more of (i) signal routing and fanout elements, (ii) impedance matching elements, (iii) signal conditioning circuits, (iv) power distribution circuits, (v) thermal management circuits, (vi) protection circuits, and the like. The signal routing and fanout elements can include copper or other metal traces on a printed circuit board (e.g., the substrate 211) of the probe card 210 that distribute signals from the test head 160 to the probe needles 2022, 2024, 2026. The traces can be selected to maintain signal integrity over short distances. Fanout can involve matching wider pitch of the connections from the test head 160 to the much finer pitch of the probe needles 2022, 2024, 2026. The impedance matching elements can include the traces, which can be or include selected widths and spacings to match characteristic impedance of the test head 160 (e.g., 50 ohms for high-frequency signals) to reduce reflections. Signal conditioning circuits can include: (i) capacitors that filter out noise or provide alternating current (AC) coupling, (ii) resistors for termination, biasing, or impedance matching, (iii) inductors for filtering or impedance matching, and the like. Power distribution circuits can include power planes, such as layers or areas on a printed circuit board (PCB) of the probe card 210 for distributing power uniformly to various regions of the probe card 210. The power distribution circuits can include decoupling capacitors that are positioned near power connections to stabilize voltage and reduce noise. Thermal management circuits or elements can include thermal vias that conduct heat away from sensitive components or areas, heat spreaders that distribute heat across the probe card 210, and the like. The protection circuits can include electrostatic discharge (ESD) protection circuits, such as diodes or varistors that protect sensitive devices from static electricity. The protection circuits can include overvoltage protection that protect sensitive devices from operational overvoltages.

In some embodiments, the probe card 210 includes signal integrity components, such as a ground planes, shielding or both, which are operable to manage return paths for signals, reduce crosstalk, control electromagnetic interference (EMI), and isolate sensitive signal paths.

In some embodiments, the MLO substrate 230 is bonded to the probe card 210 via a plurality of bumps 232. The MLO substrate 230 includes fanout traces 234. The fanout traces 234 can be or include copper traces, or other suitable conductive (e.g., metal) traces. In some embodiments, the fanout traces 234 are electrically connected to the first electronic circuits 212 and to first, second and third probe needles 2022, 2024, 2026. Generally, interconnect density in the probe card 210 and the test head 160 exceed that of the IC die region 272. Including the MLO substrate 230 is beneficial to transition interconnect density of the probe needles 2022, 2024, 2026 that contact the IC die region 272 to interconnect density of the first electronic circuits 212 and the test head 160. The MLO substrate 230 is positioned in the space or “opening” 225 defined by the jig assembly 220. In some embodiments, the MLO substrate 230 includes at least two layers of organic materials, such as polymers that can include polyimide or BT (bismaleimide triazine) resin, sandwiched between metal layers (e.g., copper). The metal layers can number from about 2 to about 20 as is beneficial to complexity of routing selection.

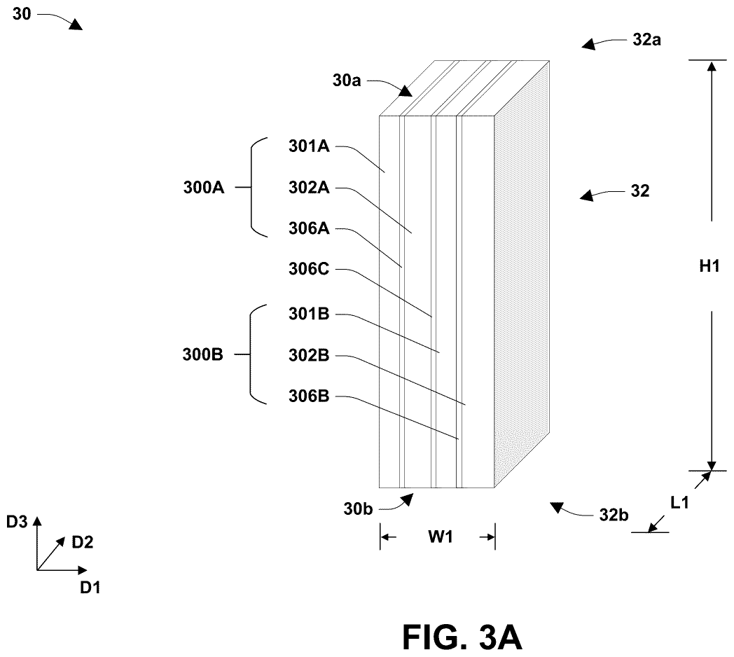

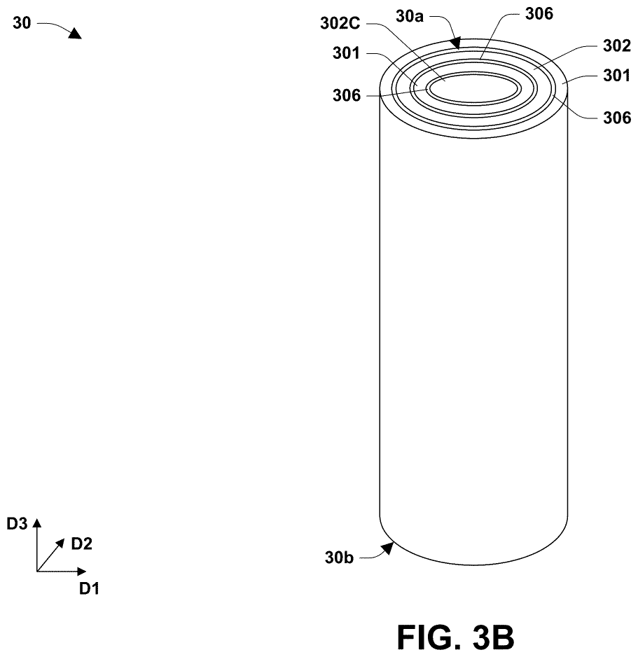

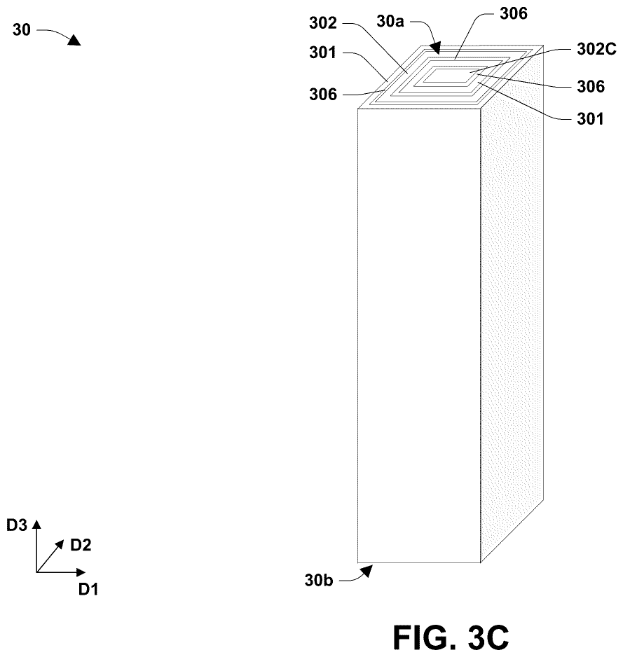

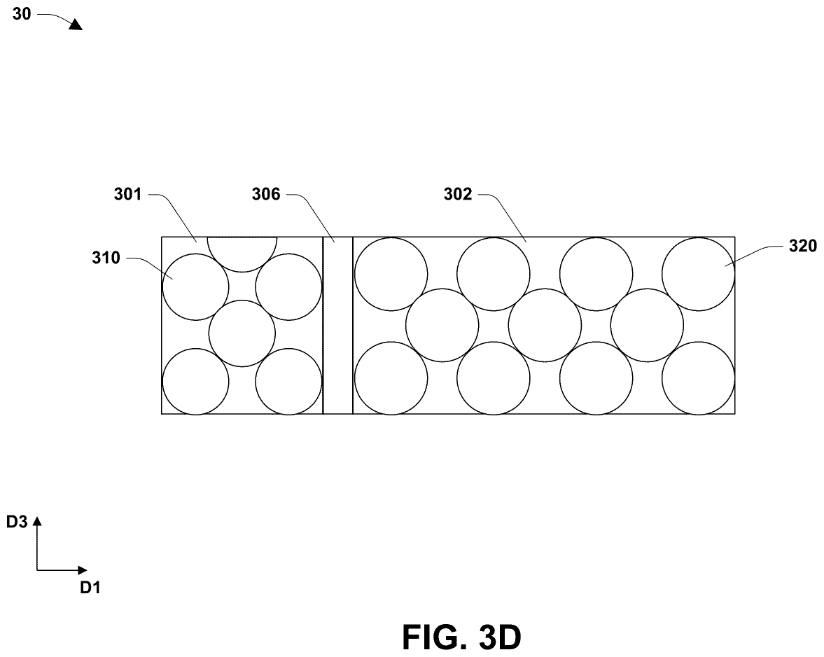

In some embodiments, each of the probe needles 2022, 2024, 2026 is a single wire probe, a micro-spring probe, a micro-electromechanical systems (MEMS) probe, a multi-layered probe, or the like. Each of the probe needles 2022, 2024, 2026 can include one or more materials, such as tungsten, rhenium, palladium, copper, silver, beryllium, gold, platinum, nickel, alloys thereof, combinations thereof, or the like. Embodiments of the probe needles 2022, 2024, 2026 are described in greater detail with reference to FIGS. 3A-3D.

The probe needles 2022, 2024, 2026 can extend from the MLO substrate 230 into and/or through the jig assembly 220. In some embodiments, the first, second and third probe needles 2022, 2024, 2026 extend through the jig assembly 220 to contact respective bumps or pads 2742, 2744, 2746 of the IC die region 272. For example, the first probe needle 2022 contacts a first bump 2742, the second probe needle 2024 contacts a second bump 2744 and the third probe needle 2026 contacts a third bump 2746. Generally, the probe needles 2022, 2024, 2026 are positioned in the opening 225 defined by the jig assembly 220 and extend vertically through the jig assembly 220 toward the wafer stage 280 positioned beneath the jig assembly 220.

The jig assembly 220 includes a jig 222, an upper die 224 attached to the jig 222, a lower die 226 and a spacer 228 that is positioned between the upper die 224 and the lower die 226.

The jig 222 is mounted to the probe card 210 and may laterally surround the MLO substrate 230, such as on four sides thereof, which can include left, right, front and back sides thereof. Top and bottom sides of the MLO substrate 230 may not be surrounded by the jig 222 in some embodiments. In some embodiments, the jig 222 is or includes a metal material, such as stainless steel or other suitable material. The jig 222 can provide benefits, including enhancing alignment precision of the probe needles 2022, 2024, 2026, improving quality of contact between the probe needles 2022, 2024, 2026 and the bumps 2742, 2744, 2746, and supporting mechanical integrity of the tester.

The jig assembly 220 can include the upper die 224, which is attached to the jig 222. The upper die 224 can be a cover that extends from four sidewalls of the jig 222 to cover the MLO substrate 230 and the underlying probe card 210. The opening 225 is defined by the jig assembly 220, such as by the jig 222 and the upper die 224. In some embodiments, the upper die 224 is or includes an insulating or dielectric material that is operable to isolate the probe needles 2022, 2024, 2026 from each other physically and electrically. The upper die 224 may define openings or holes therein, which can include first holes through which the probe needles 2022, 2024, 2026 extend. In some embodiments, each of the first holes extends along the third direction D3 (e.g., the vertical direction).

The lower die 226 is offset from the upper die 224 along the third direction D3 by the spacer 228. The lower die 226, the upper die 224, and the spacer 228 define an opening 227 through which the probe needles 2022, 2024, 2026. The lower die 226 includes first openings through which the probe needles 2022, 2024, 2026 extend to land on the pads 2742, 2744, 2746.

The spacer 228 is positioned between the upper die 224 and the lower die 226. The spacer 228 is positioned to separate the upper die 224 from the lower die 226. In some embodiments, the spacer 228 is mounted or fastened to the jig 222.

In operation, the tester to which the probe card assembly 200 is electrically connected can generate a first signal or “test signal” that is transmitted via the test head (e.g., the test head 160) to the probe card 210, which may transmit the test signal to the first pad 2742 via the MLO 230 and the first probe needle 2022. In some embodiments, the test signal is generated by test head 160 or the probe card 210 based on an electrical or control signal received from the tester. The test signal is received by electrical circuitry of the IC die region 272 via the first pad 2742. In response to the test signal, electrical circuitry generates a second signal or “response signal.” In some embodiments, the response signal is transmitted to one or more of the probe card 210, the test head 160, or the tester via the second pad 2744, the second probe needle 2024, and the MLO substrate 230. Based on the response signal, the tester may perform one or more actions associated with the DUT, which can include: (i) determining correct function, (ii) characterizing electrical performance (e.g., frequency response, harmonic distortion, gain, etc.), (iii) determining presence or absence of defects, (iv) assess reliability (e.g., stress testing), (v) determine parameter spread, (vi) determine environmental (e.g., temperature or humidity) sensitivity, (vii) determine electromagnetic (EMI) performance (e.g., EMI shielding, EMI generation, etc.), (viii) characterizing power management performance (e.g., power consumption, power integrity, etc.), (ix) determining interface and signal integrity (e.g., signal propagation, reflections, crosstalk, impedance mismatches), (x) determining safety compliance (e.g., electrical insulation, shock protection, etc.), (xi) generating debugging information (e.g., waveform analysis, timing checks, etc.), or the like. In some embodiments, one or more of the processes just described are performed by a controller that is positioned in the tester, in the test head 160, in the probe card 210, or a combination thereof.

FIG. 2B illustrates a partial diagrammatic view of a wafer test system 20, in accordance with some embodiments. The wafer test system 20 of FIG. 2B is similar in many respects to the wafer test system 20 described with reference to FIG. 2A, and like reference numerals refer to like components. Some elements of the wafer test system 20 are omitted from view or simplified in FIG. 2B.

In FIG. 2B, the wafer test system 20 is operable to perform one or more of the tests described with reference to FIG. 2A on a DUT 29 that can be or include a multichip structure that has one or more of a first die 292 and a second die 294 that are bonded to a substrate or “interposer” 290. Electrical connections to the first die 292 and the second die 294 may be via bumps 2910 of the interposer 290. In some embodiments, the first die 292 is a processor die, such as an application processor (APU), a central processor (CPU), an image processor, a graphics processor (GPU), or the like, and the second die 294 is a memory die, such as a high-bandwidth memory (HBM) or the like. In some embodiments, the DUT 29 includes additional dies that can include one or more of: (i) processor dies, (ii) memory dies, (iii) analog IC dies, (iv) interface IC dies, (v) radio frequency (RF) component dies, (vi) power management IC (PMIC) dies, (vii) security IC dies, (viii) MEMS dies, (ix) optical component dies, (x) passive components, and the like. The DUT 29 is electrically connected to the probe card assembly 200 via one or more probe needles 202 that contact the respective bumps 2910. The probe needle(s) 202 can be any of the probe needles 2022, 2024, 2026 described with reference to FIG. 2A.

The DUT 29 can undergo electrical test via the probe needle(s) 202 as described with reference to FIG. 2A. For example, the test signal may be received by the first die 292 via one of the bumps 2910. Then, the response signal may be received from the first die 292 or the second die 294 via another of the bumps 2910. In some embodiments, the first die 292 may perform data communication with the second die 294 in response to the test signal, and the first die 292 or the second die 294 may generate the response signal associated with the data communication. In some embodiments, the first die 292 may perform internal electrical functions instead of communicating with the second die 294, and may generate the response signal that is associated with the internal electrical functions. In some embodiments, the second die 294 may perform internal electrical functions instead of communicating with the first die 292 (e.g., the test signal may be transmitted directly to the second die 294), and the second die 294 may generate the response signal that is associated with the internal electrical functions thereof.

FIGS. 3A-3D illustrate diagrammatic views of probe needles 30, in accordance with some embodiments. The probe needles 30 are embodiments of the probe needles 2022, 2024, 2026, 202 described with reference to FIGS. 1-2B. Instead of an amorphous material structure that is prone to high resistance and deformation, the probe needles 30 have a super lattice structure including alternating layers of relatively high hardness material and relatively low electrical resistivity material, which is described in detail with reference to FIGS. 3A-3D. The super lattice structure can result in various benefits, including increased freedom of electron motion, selectable band gap structure, and improved structural durability.

In FIG. 3A, the probe needle 30 has a body 32 that extends along a third direction D3 (or “vertical direction D3”) and has cross-sectional profile along a plane that is transverse the third direction D3 and includes a first direction D1 and a second direction D2 that are transverse each other. The probe needle 30 has a first surface 30a at a first end 32a of the body 32 and a second surface 30b at a second end 32b of the body 32. In some embodiments, the second end 32b of the body 32 can be referred to as a “tip” of the probe needle 30. The tip or second end 32b can be operable to make physical contact with a pad of a DUT (e.g., one of the pads 2742, 2744, 2746 of the IC die region 272), a bump of the DUT (e.g., one of the bumps 2910 of the DUT 29), or the like. The first end 32a can be mounted or fixed to the probe card assembly 200, such as to the MLO substrate 230 or the probe card 210 thereof.

The body 32 includes a first multilayer structure 300A and a second multilayer structure 300B that are attached to each other. In some embodiments, the first multilayer structure 300A and the second multilayer structure 300B are attached to each other via an adhesion layer 306C (or “second adhesion layer 306C”). The first multilayer structure 300A and a second multilayer structure 300B are similar in most respects, and the first multilayer structure 300A is described in detail herein. The body 32 has width W1 in the first direction D1, length L1 in the second direction D2, and height H1 in the third direction D3. In some embodiments, the width W1 is in a range of about 30 micrometers to about 100 micrometers. In some embodiments, the length L1 is in a range of about 30 micrometers to about 100 micrometers. In some embodiments, the height H1 does not exceed about 10 millimeters, such as being in a range of about 2 millimeters to about 8 millimeters, about 3 millimeters to about 6 millimeters, or another suitable range.

The first multilayer structure 300A includes a first crystalline layer 301A. The first crystalline layer 301A extends from the first surface 30a to the second surface 30b and has the height H1 along the third direction D3. In some embodiments, the first crystalline layer 301A extends continuously from the first surface 30a to the second surface 30b. The first crystalline layer 301A can be or include a first material. In some embodiments, the first material is one of Pd, Co, Ni, Rh, or the like. In some embodiments, the first material is an alloy of Pd, Co, Ni, Rh, or the like. In some embodiments, the entire first crystalline layer 301A consists substantially of the first material (e.g., some impurities may be present at a very low concentration due to processing conditions). The first crystalline layer 301A has first hardness and first electrical resistivity. In some embodiments, the first hardness of the first crystalline layer 301A exceeds about 4.5 Mohs (i.e., 4.5 on the Mohs scale). In some embodiments, the first crystalline layer 301A has first thickness or first width in the first direction D1 that does not exceed about 50 micrometers, such as being in a range of about 15 micrometers to about 50 micrometers.

In some embodiments, the first crystalline layer 301A is substantially polycrystalline throughout the entire volume thereof. The first material being a single material of those mentioned (e.g., consisting of Pd, Co, Ni or Rh) can be beneficial to achieving high concentration of polycrystalline grains in the first crystalline layer 301A. It should be understood that “substantially polycrystalline” includes the meaning that non-crystalline features may be present in the first crystalline layer 301A at a low level compared to crystal grains of the single material or alloy. For example, percentage of volume (or “concentration”) of the non-crystalline features in the first crystalline layer 301A may be in a range of about 0.01% to about 10%, such as in a range of about 0.1% to about 1% or another suitable range. The first crystalline layer 301A having reduced concentration of non-crystalline features is beneficial to improve hardness thereof. The non-crystalline features can be or include one or more of: (i) interfacial amorphization, (ii) local amorphization, (iii) grain boundary amorphization, (iv) vacancies, interstitials or dislocations, (v) incomplete crystallizations, (vi) phase separations, (vii) top layer amorphization, (viii) strain-induced amorphization, (ix) inclusions, or the like.

In some embodiments, the first crystalline layer 301A has crystal orientation that is substantially along the second direction D2 and the second direction D3. As a result, crystallographic planes of grains of the first crystalline layer 301A may be predominantly aligned parallel to the surface of a substrate on which they are formed. For example, crystal lattice planes of the first material can lie flat in the plane of the film. As such, within the plane formed by the second direction D2 and the third direction D3, a preferential orientation of the crystals is present, such as along a selected crystallographic direction. For example, the first crystalline layer 301A may have a texture in which [100] or [111] directions are preferred to lie in the plane, such that the grains are oriented with these directions parallel to the surface instead of randomly distributed. The grains may be elongated or have a shape that preferentially stretches in the second direction D2, the third direction D3 or both, which can be a result of anisotropic growth or influence from a deposition process by which the grains are formed. Boundaries between grains may predominantly run in directions perpendicular to the plane. As such, the first crystalline layer 301A may have anisotropic electrical or thermal conductivity. Mechanical properties, such as ductility or hardness, may vary with direction due to the preferred orientation. The grains being aligned in one direction can result in surface texture or roughness that differs compared to a randomly oriented polycrystalline film. The orientation can be a result of selected atomic layer deposition (ALD) process parameters, such as substrate temperature, the nature of the surface (including any seed layers), or interaction with ALD precursors. It should be understood that, although the preferential orientation is present, some of the grains may align in a different orientation than the preferential orientation. Namely, “preferential orientation” includes the meaning that a significant majority of the grains trend towards this orientation but no requirement exists that all grains have the same orientation. For example, when the preferential orientation is along the plane formed by the second direction D2 and the third direction D3, one or more of the crystals may have some degree of variation in the first direction D1 (e.g., perpendicular to the substrate).

The first multilayer structure 300A includes a second crystalline layer 302A that is adjacent the first crystalline layer 301A and extends from the first surface 30a to the second surface 30b. The second crystalline layer 302A has the height H1 along the third direction D3. In some embodiments, the second crystalline layer 302A extends continuously from the first surface 30a to the second surface 30b. The second crystalline layer 302A can be or include a second material. In some embodiments, the second material is one of Au, Ag, Cu, or the like. In some embodiments, the entire second crystalline layer 302A consists substantially of the second material (e.g., some impurities may be present at a very low concentration due to processing conditions). The second crystalline layer 302A has second hardness and second electrical resistivity. In some embodiments, the first hardness of the first crystalline layer 301A exceeds the second hardness of the second crystalline layer 302A. In some embodiments, the first electrical resistivity of the first crystalline layer 301A exceeds the second electrical resistivity of the second crystalline layer 302A. As a result, the first crystalline layer 301A improves structural rigidity (high hardness) of the first multilayer structure 300A and the second crystalline layer 302A improves electrical conductivity (low electrical resistivity) of the first multilayer structure 300A. In some embodiments, the second electrical resistivity does not exceed about 5'10E-6 ohm-centimeters. In some embodiments, the second crystalline layer 302A has second thickness or second width in the first direction D1 that does not exceed about 50 micrometers, such as being in a range of about 15 micrometers to about 50 micrometers. In the first multilayer structure 300A, a ratio of the first width over width of the first multilayer structure 300A can be in a range of about 40% to about 60%. In the first multilayer structure 300A, a ratio of the second width over width of the first multilayer structure 300A can be in a range of about 40% to about 60%. Ratio of volume of the first material over volume of the first multilayer structure 300A may be in a range of about 40% to about 60%. Ratio of volume of the second material over volume of the first multilayer structure 300A may be in a range of about 40% to about 60%. In some embodiments, ratio of first width of the first crystalline layer 301A over second width of the second crystalline layer 302A is in a range of about 0.6 to about 1.5. In some embodiments, ratio of first thickness of the first material over second thickness of the second material in the body 32 is in a range of about 0.6 to about 1.5.

In some embodiments, the second crystalline layer 302A is substantially polycrystalline throughout the entire volume thereof. The second material being a single material of those mentioned (e.g., consisting of Au, Ag or Cu) can be beneficial to achieving high concentration of polycrystalline grains in the second crystalline layer 302A. It should be understood that “substantially polycrystalline” includes the meaning that non-crystalline features may be present in the second crystalline layer 302A at a low level compared to crystal grains of the single material or alloy. For example, percentage of volume (or “concentration”) of the non-crystalline features in the second crystalline layer 302A may be in a range of about 0.01% to about 10%, such as in a range of about 0.1% to about 1% or another suitable range. The second crystalline layer 302A having reduced concentration of non-crystalline features is beneficial to improve hardness thereof. The non-crystalline features can be or include one or more of: (i) interfacial amorphization, (ii) local amorphization, (iii) grain boundary amorphization, (iv) vacancies, interstitials or dislocations, (v) incomplete crystallizations, (vi) phase separations, (vii) top layer amorphization, (viii) strain-induced amorphization, (ix) inclusions, or the like.

In some embodiments, the second crystalline layer 302A has crystal orientation that is substantially along the second direction D2 and the second direction D3. As a result, crystallographic planes of grains of the second crystalline layer 302A may be predominantly aligned parallel to the surface of a substrate on which they are formed. For example, crystal lattice planes of the first material can lie flat in the plane of the film. As such, within the plane formed by the second direction D2 and the third direction D3, a preferential orientation of the crystals is present, such as along a selected crystallographic direction. For example, the second crystalline layer 302A may have a texture in which [100] or [111] directions are preferred to lie in the plane, such that the grains are oriented with these directions parallel to the surface instead of randomly distributed. The grains may be elongated or have a shape that preferentially stretches in the second direction D2, the third direction D3 or both, which can be a result of anisotropic growth or influence from a deposition process by which the grains are formed. Boundaries between grains may predominantly run in directions perpendicular to the plane. As such, the second crystalline layer 302A may have anisotropic electrical or thermal conductivity. Mechanical properties, such as ductility or hardness, may vary with direction due to the preferred orientation. The grains being aligned in one direction can result in surface texture or roughness that differs compared to a randomly oriented polycrystalline film. The orientation can be a result of selected atomic layer deposition (ALD) process parameters, such as substrate temperature, the nature of the surface (including any seed layers), or interaction with ALD precursors. It should be understood that, although the preferential orientation is present, some of the grains may align in a different orientation than the preferential orientation. Namely, “preferential orientation” includes the meaning that a significant majority of the grains trend towards this orientation but no requirement exists that all grains have the same orientation. For example, when the preferential orientation is along the plane formed by the second direction D2 and the third direction D3, one or more of the crystals may have some degree of variation in the first direction D1 (e.g., perpendicular to the substrate).

The first multilayer structure 300A includes an adhesion layer 306A (or “first adhesion layer 306A”) that extends continuously from the first surface 30a to the second surface 30b. The first adhesion layer 306A is positioned between the first crystalline layer 301A and the second crystalline layer 302A. In some embodiments, the first adhesion layer 306A includes a third material that is different than the first material and different than the second material. In some embodiments, the third material is or includes one or more of Cr, Ti, Al, Ni, W, Pt, Au, TiO₂, Ru, Rh, an alloy thereof, combinations thereof, or the like. In some embodiments, the first adhesion layer 306A has third thickness or third width in the first direction D1 that does not exceed about 3 micrometers, such as being in a range of about 0.5 micrometers to about 3 micrometers. The first adhesion layer 306A is beneficial to prevent delamination of the first crystalline layer 301A from the second crystalline layer 302A.

The second multilayer structure 300B can be similar in most respects to the first multilayer structure 300A. For example, the second multilayer structure 300B can include a third crystalline layer 301B that extends continuously from the first surface 30a to the second surface 30b and has the first material. The second multilayer structure 300B can include a fourth crystalline layer 410302B that extends continuously from the first surface 30a to the second surface 30b and has the second material. The second multilayer structure 300B can include a third adhesion layer 306B between the fourth crystalline layer 302B and the third crystalline layer 301B. The third crystalline layer 301B is similar in most respects to the first crystalline layer 301A. The fourth crystalline layer 302B is similar in most respects to the second crystalline layer 302A. The third adhesion layer 306B is similar in most respects to the first adhesion layer 306A and the second adhesion layer 306C.

In some embodiments, the first multilayer structure 300A and the second multilayer structure 300B may be similar in most respects or may be different in one or more respects. For example, ratio of the first width of the first crystalline layer 301A over the second width of the second crystalline layer 302A may be different than (e.g., exceed or be less than) ratio of a third width of the third crystalline layer 301B over a fourth width of the fourth crystalline layer 302B. In another example, the first material of the first crystalline layer 301A may be different than a third material of the third crystalline layer 301B. For example, the first material may be one of Pd, Co, Ni, Rh and the third material may be another of Pd, Co, Ni, Rh different than the one. In another example, the second material of the second crystalline layer 302A may be different than a fourth material of the fourth crystalline layer 302B. For example, the second material may be one of Au, Ag, or Cu and the fourth material may be another of Au, Ag, or Cu different than the one.

FIG. 3A illustrates the body 32 including two multilayer structures, namely, the first multilayer structure 300A and the second multilayer structure 300B. In some embodiments, the body 32 can include one or more additional multilayer structures similar to the first multilayer structure 300A and/or the second multilayer structure 300B. For example, the body 32 can include a super lattice structure that includes the first, second, third and fourth crystalline layers 301A, 302A, 301B, 302B, and can further include a fifth crystalline layer similar to the first crystalline layer 301A, a sixth crystalline layer similar to the second crystalline layer 302A, and so on.

FIG. 3B illustrates a diagrammatic view of a probe needle 30, in accordance with some embodiments.

In FIG. 3B, the probe needle 30 includes a center crystalline layer 302C that is similar in most respects to the second crystalline layer 302A described with reference to FIG. 3A. The center crystalline layer 302C may be circular or elliptical in profile in the plane formed by the first direction and the second direction. The center crystalline layer 302C may include the second material, such as Au, Ag, Cu, or the like. In a radial direction, alternating first crystalline layers 301, adhesion layers 306 and second crystalline layers 302 laterally surround the center crystalline layer 302C. For example, the center crystalline layer 302C may be surrounded by an adhesion layer 306, which may be surrounded by a first crystalline layer 301, which may be surrounded by another adhesion layer 306, which may be surrounded by a second crystalline layer 302, and so on. Ratio of volume of the center crystalline layer 302C and the second crystalline layers 302 over volume of the probe needle 30 may be in a range of about 40% to about 60%. Ratio of volume of the first crystalline layers 301 over volume of the probe needle 30 may be in a range of about 40% to about 60%. The structure depicted in FIG. 3B of the probe needle 30 can be described as the probe needle 30 having the first crystalline layers 301 and the second crystalline layers 302 that are arranged as concentric cylindrical rings. In some embodiments, diameter of the probe needle 30 of FIG. 3B in the plane formed by the first direction D1 and the second direction D2 is in a range of about 30 micrometers to about 100 micrometers.

FIG. 3C illustrates a diagrammatic view of a probe needle 30, in accordance with some embodiments. The probe needle 30 depicted in FIG. 3C is similar in most respects to the probe needle 30 described with reference to FIG. 3B.

In FIG. 3C, instead of concentric cylindrical rings, the first crystalline layers 301 and the second crystalline layers 302 are arranged as concentric rectangular or square rings. In some embodiments, width and length of the probe needle 30 of FIG. 3C in the plane formed by the first direction D1 and the second direction D2 are each in a range of about 30 micrometers to about 100 micrometers.

FIG. 3D illustrates a partial view of the probe needle 30 of FIG. 3A that includes the first crystalline layer 301, the adhesion layer 306 and the second crystalline layer 302. The probe needles 30 described with reference to FIGS. 3B and 3C may have similar structure as that described with reference to FIG. 3D.

The first crystalline layer 301 includes the first material 310, which has first crystalline structure that is oriented along the plane including the third direction D3 and the second direction D2. The second crystalline layer 302 includes the second material 320, which has second crystalline structure that is oriented along the plane including the third direction D3 and the second direction D2. In some embodiments, the first crystalline structure is different than the second crystalline structure. For example, the first crystalline structure may be more tightly packed than the second crystalline structure. In another example, the first crystalline structure may have smaller grain size(s) than the second crystalline structure.

The first material 310 has hardness and electrical resistivity that exceed those of the second material 320. As such, electrical current flow through the second material 320 may exceed that through the first material 310. The first material 310 can provide structural rigidity to the probe needle 30, and the second material 320 can provide reduced voltage drop across the probe needle 30. As a result, the probe needle 30 can have improved durability and improved speed performance.

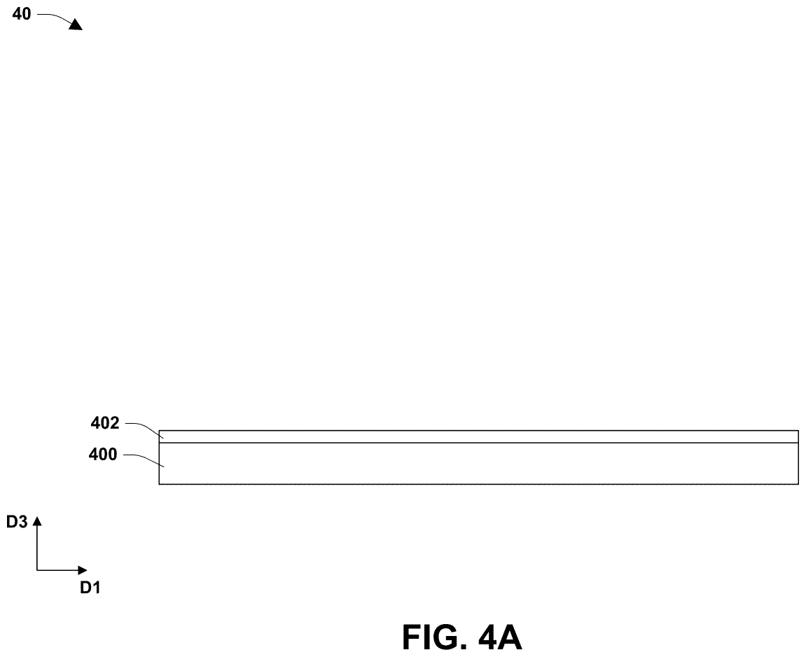

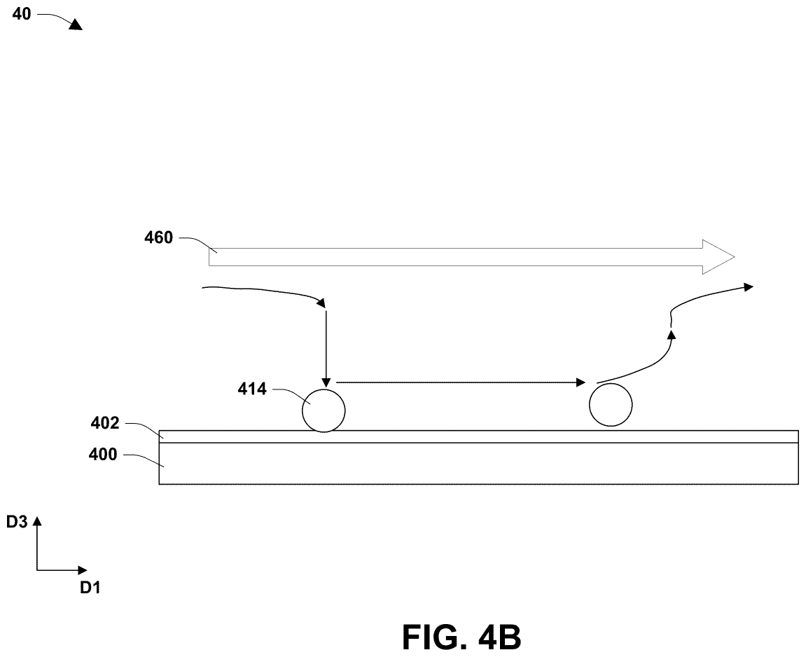

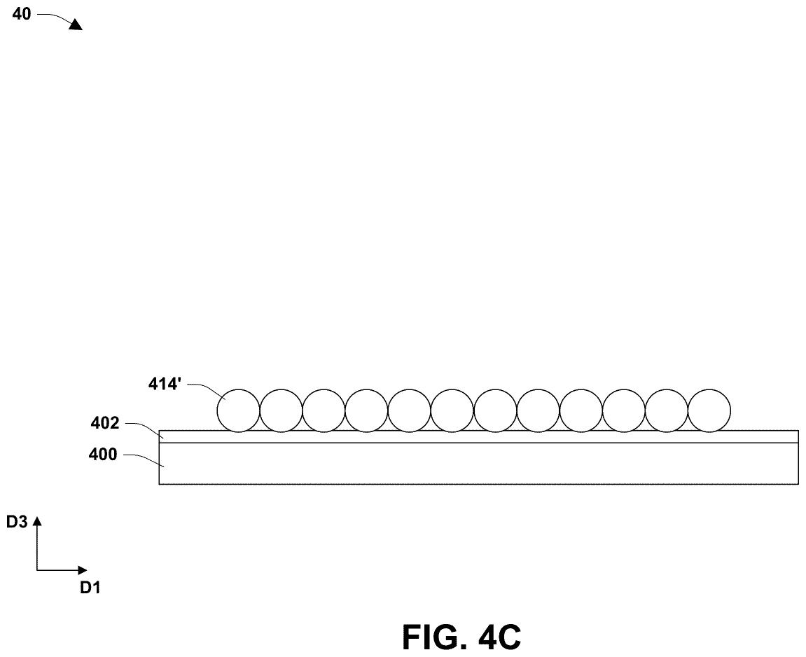

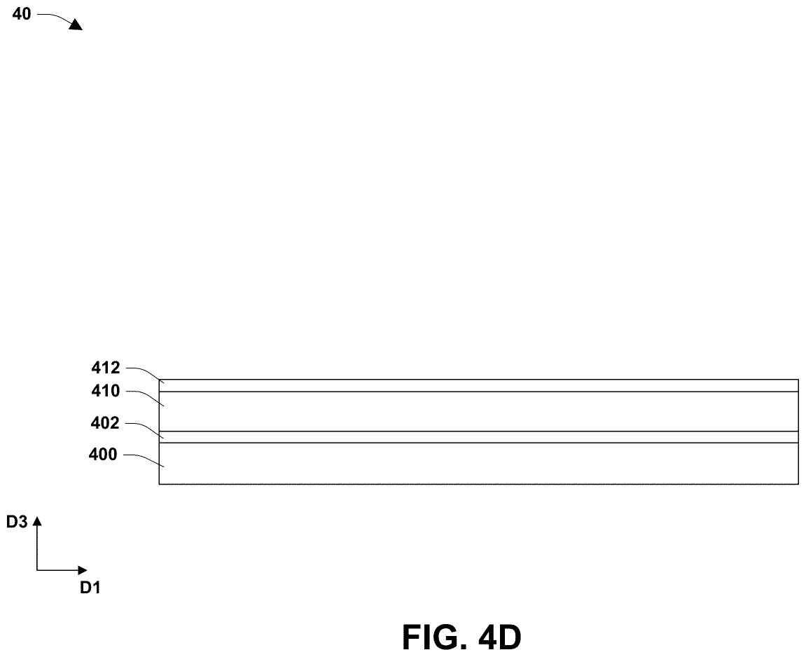

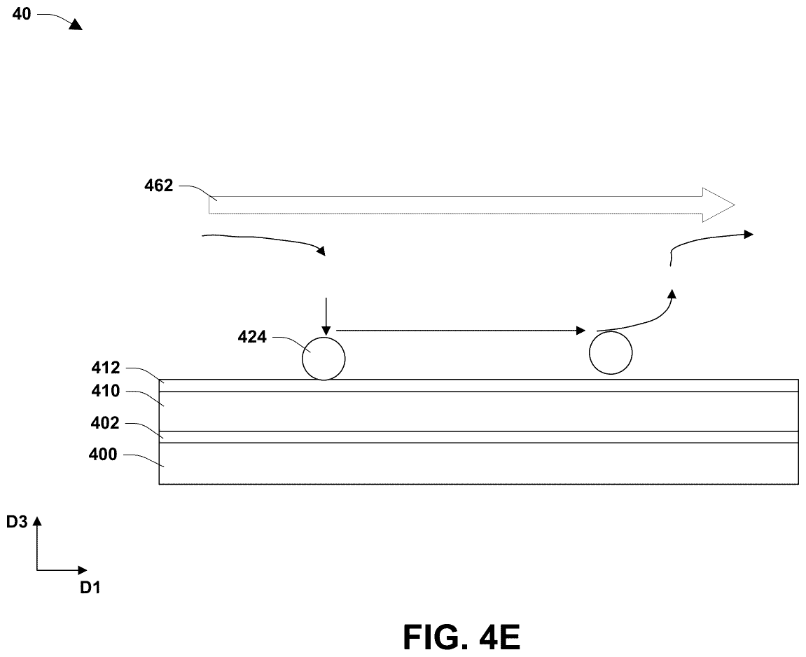

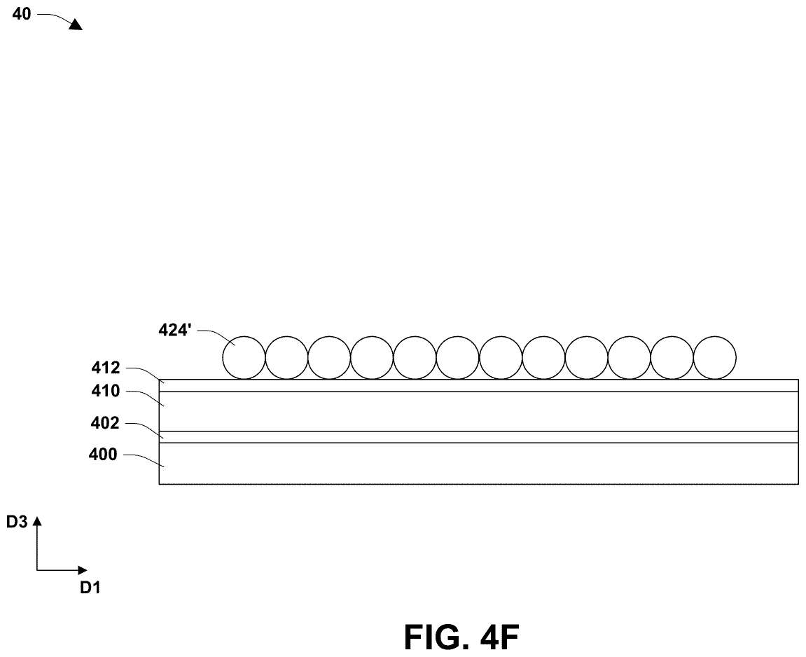

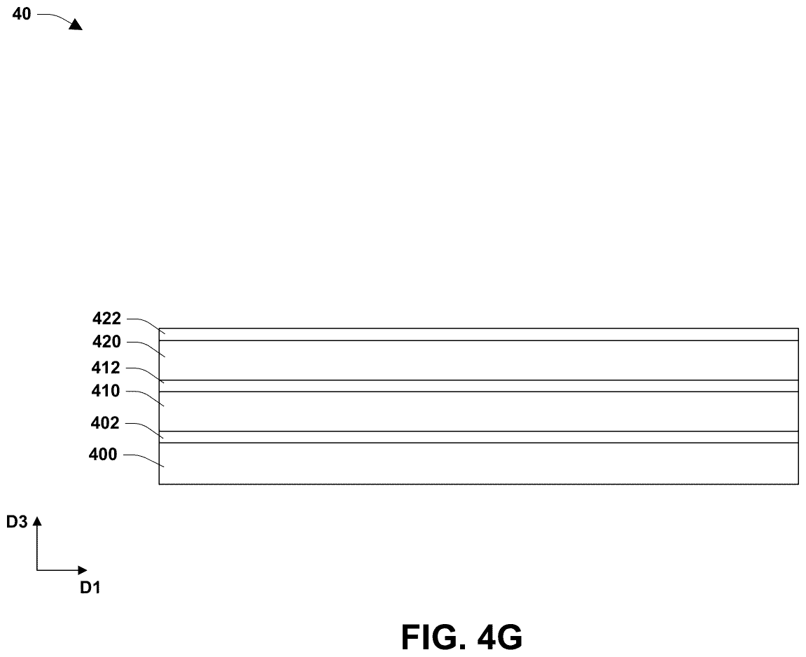

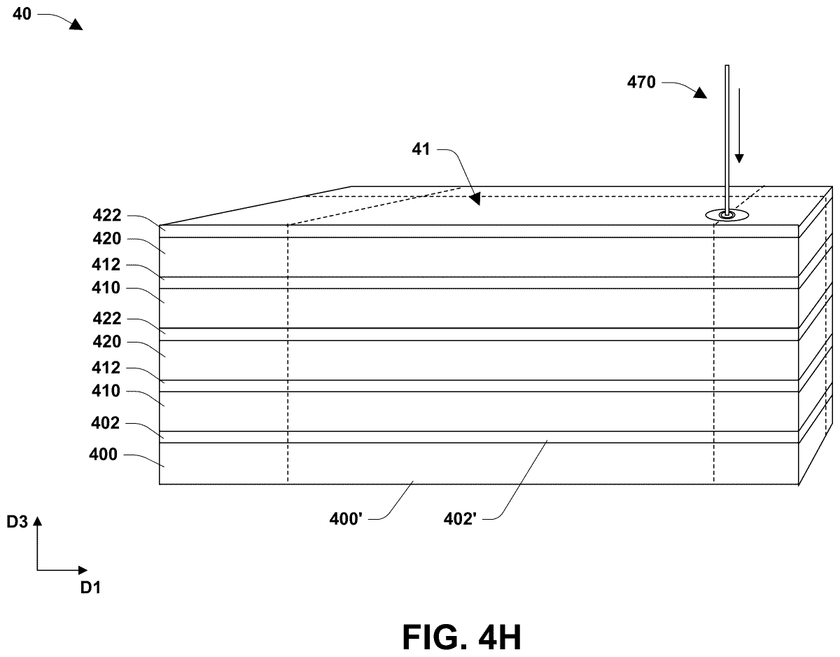

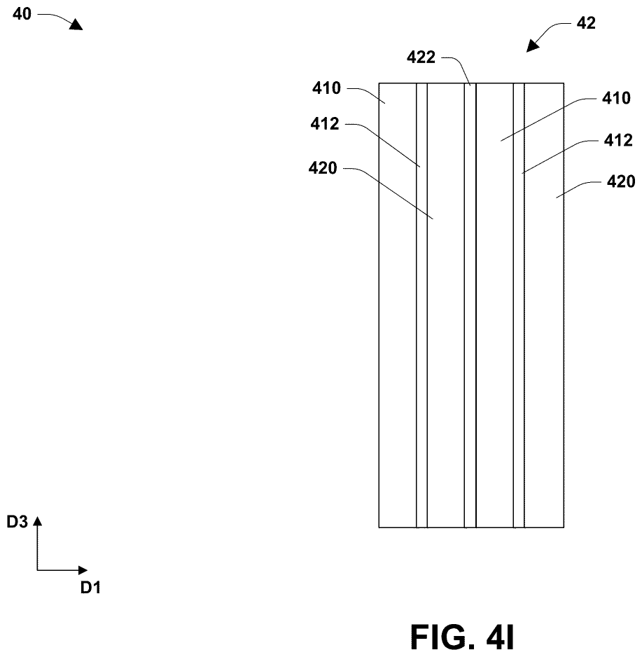

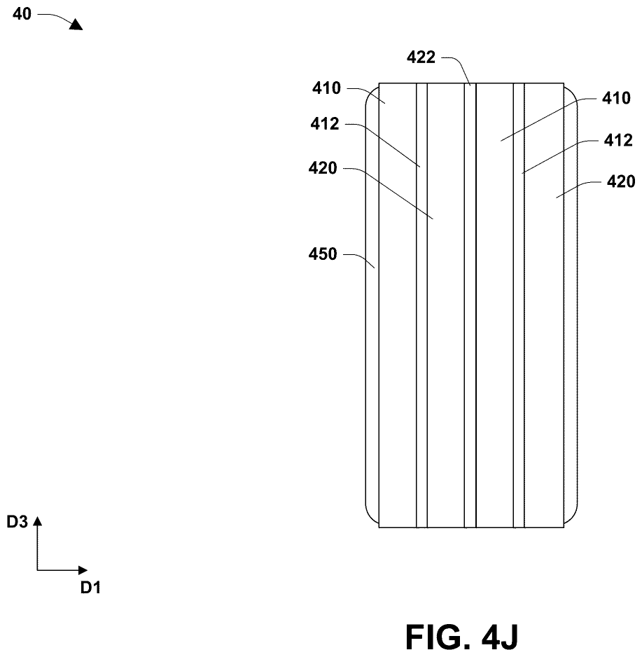

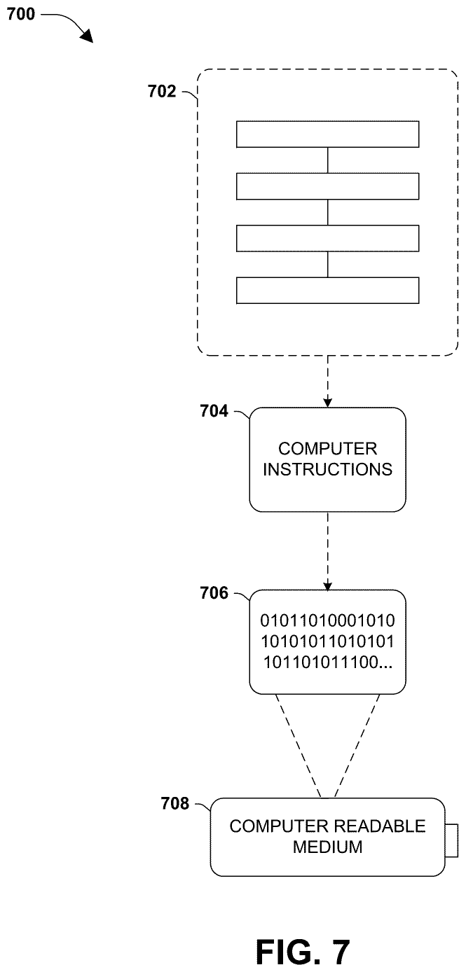

FIGS. 4A, 4B, 4C, 4D, 4E, 4F, 4G, 4H, 4I, and 4J are diagrammatic views of a method of forming a probe needle 40, in accordance with some embodiments. FIGS. 4A-4J depict the probe needle 40 at intermediate stages of formation. The method is described with reference to a method 700 that is illustrated in FIG. 7.

In FIG. 4A, a substrate 400 is provided. In some embodiments, the substrate 400 is a semiconductor wafer. In some embodiments, the substrate 400 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. In some embodiments, the substrate 400 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the substrate 400 are within the scope of the present disclosure.

A seed layer 402 (or “adhesion layer 402”) is formed on the substrate 400. In some embodiments, the seed layer 402 is or includes one or more of Cr, Ti, Al, Ni, W, Pt, Au, TiO₂, Ru, Rh, a multilayer thereof, a combination thereof, or the like. In some embodiments, thickness of the seed layer 402 does not exceed about 3 micrometers. In some embodiments, the seed layer 402 is formed by a first deposition process, which can include one or more of sputtering, evaporation, ALD, electroplating, or chemical vapor deposition (CVD), such as low-pressure chemical vapor deposition (LPCVD), metal-organic chemical vapor deposition (MOCVD), plasma-enhanced chemical vapor deposition (PECVD), hot filament chemical vapor deposition (HFCVD), laser-assisted chemical vapor deposition (LACVD), atmospheric pressure chemical vapor deposition (APCVD), or the like. Prior to depositing the seed layer 402, the first deposition process can include a surface preparation or treatment operation, which can include cleaning by RCA (e.g., SC-1, SC-2) and an optional HF dip. Follow depositing the seed layer 402, a post-deposition annealing operation may be performed, and one or more surface treatments may be performed on the seed layer 402.

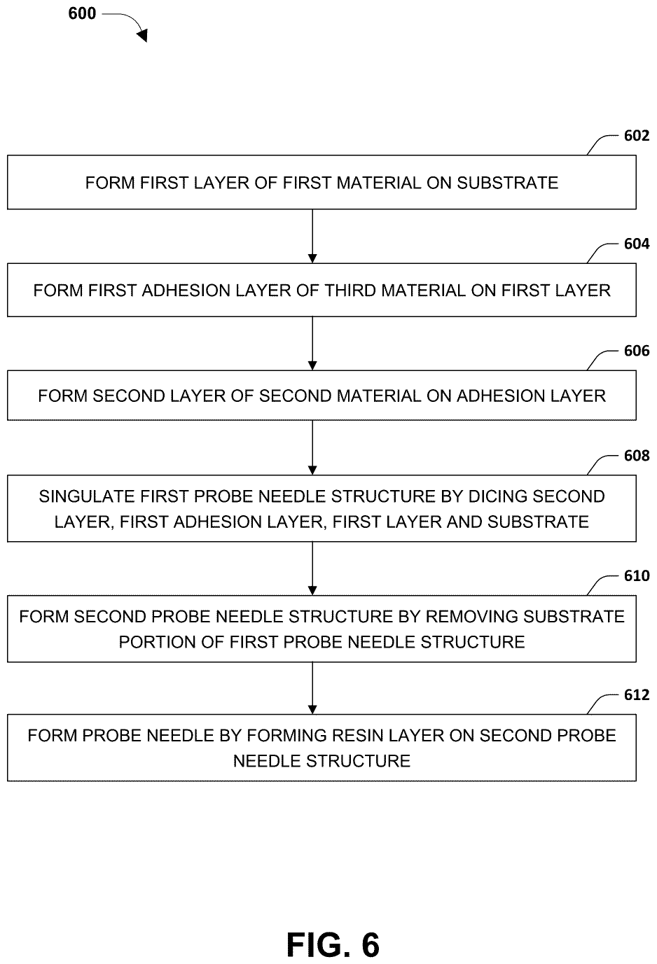

In FIGS. 4B-4D, a first crystalline layer 410 is formed on the seed layer 402, corresponding to act 602 of FIG. 6.

In FIG. 4B, following formation of the seed layer 402, a first precursor 460 is flowed towards and across the substrate 400 and the seed layer 402 to deposit precursor molecules 414 for depositing a first material of the first crystalline layer 410. In some embodiments, the first material is or includes one or more of Pd, Co, Ni, Rh or the like. The first material can have hardness that exceeds about 4.5 Mohs. The first precursor 460 is depicted as an arrow that indicates direction in which the precursor gas (e.g., containing Pd, Co, Ni, or Rh) is delivered towards the substrate 400, such as along the first direction D1. In some embodiments, the directional flow of the first precursor 460 is part of a CVD or ALD operation in which the precursor gas is transported in a controlled manner. As the precursor molecules 414 approach the surface of the seed layer 402, the precursor molecules 414 can interact with the seed layer 402. The seed layer 402 is beneficial to provide a surface that improves adhesion of deposited metal thereto, and to promote nucleation of metal atoms from the first precursor 460, increasing uniformity of the first crystalline layer 410. The detailed process flow begins with the transport of the first precursor 460 towards the surface of the substrate 400 (or seed layer 402), as indicated by the leftmost arrows, where the precursor molecules 414 adsorb onto the seed layer 402. Following adsorption, the precursor molecules 414 undergo surface kinetics, involving chemical reactions that can include thermal decomposition or reactions with surface groups, which select rate and uniformity of film growth of the first crystalline layer 410. Subsequently, byproducts or unreacted parts of the precursor molecules 414 desorb from the surface of the seed layer 402, clearing the seed layer 402 for the next deposition event. Desorbed species are transported away from the substrate by the gas flow, as shown by the rightmost arrows pointing away, completing a cycle that forms thin films of the first material (e.g., Pd, Co, Ni, Rh or the like) in processes such as CVD or ALD. A first sublayer of the first crystalline layer 410 that includes atoms 414′ of the first material is depicted in FIG. 4C. The first crystalline layer 410 is depicted in FIG. 4D. In some embodiments, first thickness of the first crystalline layer 410 along the third direction D3 is in a range of about 10 micrometers to about 100 micrometers. In some embodiments, the first thickness is less than about 10 micrometers, such as in a range of about 2 micrometers to about 10 micrometers.

In FIG. 4D, following formation of the first crystalline layer 410, a first adhesion layer 412 (or “seed layer 412”) is formed on the first crystalline layer 410, corresponding to act 604 of FIG. 6. Formation of the first adhesion layer 412 can be similar in most respects to formation of the seed layer 402 described with reference to FIG. 4A. In some embodiments, the first adhesion layer 412 is or includes one or more of Cr, Ti, Al, Ni, W, Pt, Au, TiO₂, Ru, Rh, a multilayer thereof, a combination thereof, or the like. In some embodiments, thickness of the first adhesion layer 412 does not exceed about 3 micrometers. In some embodiments, the first adhesion layer 412 is formed by a first deposition process, which can include one or more of sputtering, evaporation, ALD, electroplating, or chemical vapor deposition (CVD). In some embodiments, the first adhesion layer 412 is or includes the same material as or a different material than the seed layer 402. For example, the seed layer 402 may be a first adhesion material that is beneficial for adhering the first crystalline layer 410 to the material of the substrate 400 (e.g., silicon), and the first adhesion layer 412 may be a second adhesion material that is beneficial for adhering the first crystalline layer 410 to a subsequently-formed second crystalline layer 420.

In FIGS. 4E-4G, a second crystalline layer 420 is formed on the first adhesion layer 412, corresponding to act 606 of FIG. 6.

In FIG. 4E, following formation of the first adhesion layer 412, a second precursor 462 is flowed towards and across the first adhesion layer 412 to deposit precursor molecules 424 for depositing a second material of the second crystalline layer 420. In some embodiments, the second material is or includes one or more of Ag, Cu, Au, or the like. The second material can have electrical resistance that does not exceed about 5×10E-6. The second precursor 462 is depicted as an arrow that indicates direction in which the precursor gas (e.g., containing Pd, Co, Ni, or Rh) is delivered towards the substrate 400, such as along the first direction D1. In some embodiments, the directional flow of the second precursor 462 is part of a CVD or ALD operation in which the precursor gas is transported in a controlled manner. As the precursor molecules 424 approach the surface of the first adhesion layer 412, the precursor molecules 424 can interact with the first adhesion layer 412. The first adhesion layer 412 is beneficial to provide a surface that improves adhesion of deposited metal thereto, and to promote nucleation of metal atoms from the second precursor 462, increasing uniformity of the second crystalline layer 420. The detailed process flow begins with the transport of the second precursor 462 towards the surface of the first adhesion layer 412, as indicated by the leftmost arrows, where the precursor molecules 424 adsorb onto the first adhesion layer 412. Following adsorption, the precursor molecules 424 undergo surface kinetics, involving chemical reactions that can include thermal decomposition or reactions with surface groups, which select rate and uniformity of film growth of the second crystalline layer 420. Subsequently, byproducts or unreacted parts of the precursor molecules 424 desorb from the surface of the first adhesion layer 412, clearing the first adhesion layer 412 for the next deposition event. Desorbed species are transported away from the substrate by the gas flow, as shown by the rightmost arrows pointing away, completing a cycle that forms thin films of the second material (e.g., Pd, Co, Ni, Rh or the like) in processes such as CVD or ALD. A first sublayer of the second crystalline layer 420 that includes atoms 424′ of the second material is depicted in FIG. 4F. The second crystalline layer 420 is depicted in FIG. 4G. In some embodiments, first thickness of the second crystalline layer 420 along the third direction D3 is in a range of about 10 micrometers to about 100 micrometers. In some embodiments, the first thickness is less than about 10 micrometers, such as in a range of about 2 micrometers to about 10 micrometers.

In FIG. 4G, following formation of the second crystalline layer 420, a second adhesion layer 422 (or “seed layer 422”) is formed on the second crystalline layer 420. Formation of the second adhesion layer 422 can be similar in most respects to formation of the seed layer 402 and the first adhesion layer 412 described with reference to FIGS. 4A and 4D. In some embodiments, the second adhesion layer 422 is or includes one or more of Cr, Ti, Al, Ni, W, Pt, Au, TiO₂, Ru, Rh, a multilayer thereof, a combination thereof, or the like. In some embodiments, thickness of the second adhesion layer 422 does not exceed about 3 micrometers. In some embodiments, the second adhesion layer 422 is formed by a first deposition process, which can include one or more of sputtering, evaporation, ALD, electroplating, or chemical vapor deposition (CVD). In some embodiments, the second adhesion layer 422 is or includes the same material as or a different material than the first adhesion layer 412.

The operations described with reference to FIGS. 4A-4G can be repeated to form additional first crystalline layers 410, second crystalline layers 420, first adhesion layers 412 and second adhesion layers 422. A resulting structure of the probe needle 40 is depicted in FIG. 4H.

Then, as depicted in FIG. 4H, a first probe needle structure 41 is formed by singulating (e.g., dicing) the second crystalline layer(s) 420, the first adhesion layer(s) 412, the first crystalline layer(s) 410, the second adhesion layer(s) 422, and optionally the seed layer 402 and the substrate 400, corresponding to act 608 of FIG. 6. In some embodiments, the singulation can be performed by laser cutting 470.

To reduce damage to crystalline structure of the individual layers during formation of the first probe needle structure 41, such as during laser cutting, several strategies can be employed. For example, the laser can be a femtosecond or picosecond lasers, which has benefit of reducing a heat-affected zone (HAZ) due to an ability to ablate material before thermal diffusion occurs. In another example, cold ablation techniques, where the laser energy is absorbed by the respective material in such a way that it directly transitions into a plasma or vapor without passing through a liquid phase, can reduce thermal damage. Reducing laser power and including higher repetition rates or very short pulses can reduce energy input per unit time, reducing heat transfer and thereby preserving the lattice structure. Water-assisted laser cutting that implements water or another liquid medium during the laser cutting process can act as a coolant, absorbing excess heat and reducing the HAZ, which can reduce excessive heating. Cutting in an inert gas atmosphere such as argon or nitrogen can prevent oxidation, which can otherwise introduce defects or alter surface properties of the lattice. The inert gas environment can improve cooling and debris removal. In some embodiments, cutting includes multi-pass cutting, such that, instead of cutting through the entire stack or entire layer in a single pass, multiple lighter passes can distribute energy input over time, reducing peak temperature at any point, thereby reducing thermal shock and preserving the crystalline order. Following laser cutting, a post-cutting anneal can be performed, which can include a controlled, low-temperature annealing process that relieves residual stresses introduced by the cutting process, which can result in recovery of crystalline defects without altering the overall structure significantly.

Following singulation, each of the first probe needle structures 41 includes a substrate portion 400′ and a seed layer portion 402′.

In FIG. 4I, following formation of the first probe needle structure 41, a second probe needle structure 42 is formed by removing the substrate portion 400′, corresponding to act 610 of FIG. 6. In some embodiments, the seed layer portion 402′ is removed. Removal of the substrate portion 400′ and optionally the seed layer portion 402′ can be by delamination, in some embodiments. The delamination may include one or more of peel-off, flexing, selective etching, solvent release, or another suitable delamination method.

In FIG. 4J, the probe needle 40 is formed by forming a resin layer 450 on the second probe needle structure 42, corresponding to act 612 of FIG. 6. In some embodiments, the resin layer 450 is formed by a coating process that includes a spin coating operation.

The probe needle 40 has the lattice structure that includes alternating first crystalline layers 410 and second crystalline layers 420 that are optionally adhered to each other via first adhesion layers 412 and second adhesion layers 422. The lattice structure reduces electrical resistance of the probe needle 40 via the second crystalline layers having low electrical resistance, while increasing structural integrity thereof via the first crystalline layers that have high hardness. As a result, burning of the probe needle 40 is reduced and electrical performance of the probe needle 40 is increased.

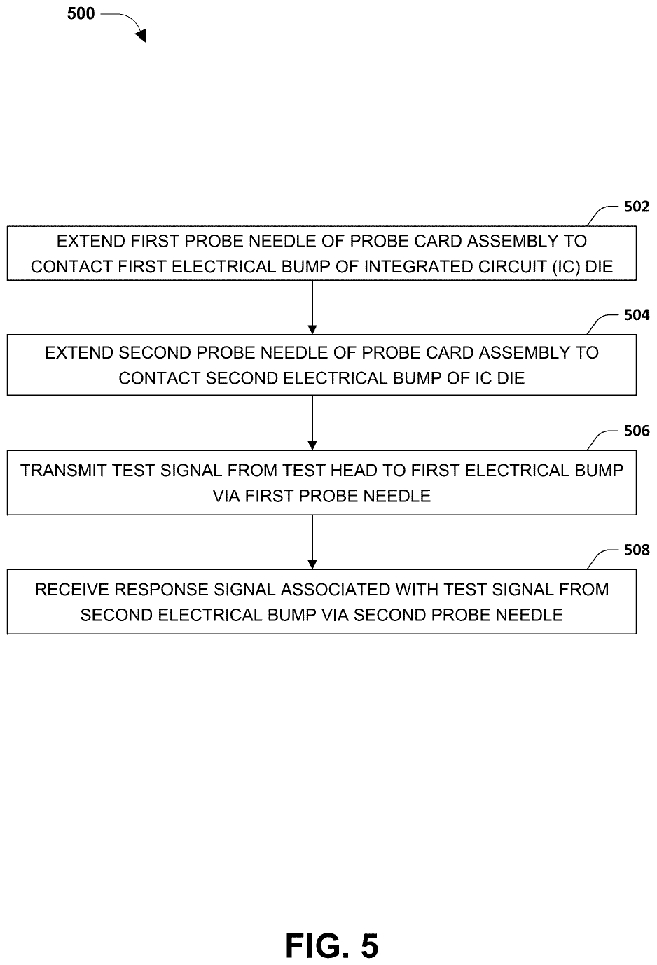

A method 500 is illustrated in FIG. 5 in accordance with some embodiments.

At 502, the method 500 includes extending a first probe needle of a probe card assembly to contact a first electrical bump of an integrated circuit (IC) die. The first probe needle includes: a first crystalline layer extending from a first end of the probe needle to a second end of the probe needle, the first crystalline layer having a first resistivity; and a second crystalline layer extending from the first end to the second end and positioned adjacent the first crystalline layer, the second crystalline layer having crystalline structure that is different than that of the first crystalline layer and having a second resistivity that is less than the first resistivity.

At 504, the method 500 includes extending a second probe needle of the probe card assembly to contact a second electrical bump of the IC die.

At 506 and 508, the method 500 includes performing an electrical test on the IC die by a test head in electrical communication with the probe card assembly.

At 506, the method 500 includes transmitting a test signal from the test head to the first electrical bump via the first probe needle.

At 508, the method 500 includes receiving a response signal associated with the test signal from the second electrical bump via the second probe needle.

A method 600 is illustrated in FIG. 6 in accordance with some embodiments.

At 602, the method 600 includes forming a first crystalline layer on a substrate, the first crystalline layer including a first material.

At 604, the method 600 includes forming a first adhesion layer on the first crystalline layer, the first adhesion layer including a third material that is different than the first material.

At 606, the method 600 includes forming a second crystalline layer on the first adhesion layer, the second crystalline layer including a second material that is different than the first material and the third material.

At 608, the method 600 includes singulating a first probe needle structure by dicing the second crystalline layer, the first adhesion layer, the first crystalline layer and the substrate.

At 610, the method 600 includes forming a second probe needle structure by removing a substrate portion of the first probe needle structure.

At 612, the method 600 includes forming a probe needle by forming a resin layer on the second probe needle structure.

One or more embodiments involve a computer-readable medium comprising processor-executable instructions configured to implement one or more of the techniques presented herein. An exemplary computer-readable medium is illustrated in FIG. 7, wherein the embodiment 700 comprises a computer-readable medium 707 (e.g., a CD-R, DVD-R, flash drive, a platter of a hard disk drive, etc.), on which is encoded computer-readable data 706. This computer-readable data 706 in turn comprises a set of processor-executable computer instructions 704 configured to implement one or more of the principles set forth herein when executed by a processor. In some embodiments 700, the processor-executable computer instructions 704 are configured to implement a method 702, such as at least some of the aforementioned method(s) when executed by a processor. In some embodiments, the processor-executable computer instructions 704 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: extending a first probe needle of a probe card assembly to contact a first electrical bump of an integrated circuit (IC) die, the first probe needle including: a first crystalline layer extending from a first end of the first probe needle to a second end of the first probe needle, the first crystalline layer including a first crystalline structure and a first resistivity; and a second crystalline layer extending from the first end to the second end and positioned adjacent the first crystalline layer, the second crystalline layer having crystalline structure that is different than that of the first crystalline layer and having a second resistivity that is less than the first resistivity. The method includes: extending a second probe needle of the probe card assembly to contact a second electrical bump of the IC die; and performing an electrical test on the IC die by a test head in electrical communication with the probe card assembly, which includes: transmitting a test signal from the test head to the first electrical bump via the first probe needle; and receiving a response signal associated with the test signal from the second electrical bump via the second probe needle.

In some embodiments, a method is provided. The method includes: forming a first crystalline layer on a substrate, the first crystalline layer including a first material; forming a first adhesion layer on the first crystalline layer, the first adhesion layer including a third material that is different than the first material; forming a second crystalline layer on the first adhesion layer, the second crystalline layer including a second material that is different than the first material and the third material; singulating a first probe needle structure by dicing the second crystalline layer, the first adhesion layer, the first crystalline layer and the substrate; forming a second probe needle structure by removing a substrate portion of the first probe needle structure; and forming the probe needle by forming a resin layer on the second probe needle structure.

In some embodiments, a structure is provided. The structure includes: a first surface that, in operation, is in electrical contact with a probe card of a test apparatus; a second surface that, in operation, is in electrical contact with an electrical connection structure of an integrated circuit (IC) die; a first crystalline layer that extends continuously from the first surface to the second surface, the first crystalline layer having a first material, a first hardness and first electrical resistivity; and a second crystalline layer that is adjacent the first crystalline layer and extends continuously from the first surface to the second surface, the second crystalline layer having a second material, a second hardness and a second electrical resistivity, the second material being different than the first material.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
extending a first probe needle of a probe card assembly to contact a first electrical bump of an integrated circuit (IC) die, the first probe needle including:
a first crystalline layer extending from a first end of the first probe needle to a second end of the first probe needle, the first crystalline layer having a first resistivity; and
a second crystalline layer extending from the first end to the second end and positioned adjacent the first crystalline layer, the second crystalline layer having crystalline structure that is different than that of the first crystalline layer and having a second resistivity that is less than the first resistivity;
extending a second probe needle of the probe card assembly to contact a second electrical bump of the IC die; and
performing an electrical test on the IC die by a test head in electrical communication with the probe card assembly, including:
transmitting a test signal from the test head to the first electrical bump via the first probe needle; and
receiving a response signal associated with the test signal from the second electrical bump via the second probe needle.

2. The method of claim 1, wherein extending the first probe needle includes:
extending the first probe needle that has the first crystalline layer having a first hardness that exceeds a second hardness of the second crystalline layer.

3. The method of claim 1, wherein extending the first probe needle includes:
extending the first probe needle that has an adhesion layer positioned between the first crystalline layer and the second crystalline layer.

4. The method of claim 3, wherein extending the first probe needle includes:
extending the first probe needle that has:
the first crystalline layer that includes a first metal having hardness that exceeds about 4.5 Mohs;
the second crystalline layer that includes a second metal having the second resistivity that does not exceed about 5×10E-6 ohm-centimeters; and
the adhesion layer that includes Cr, Ti, Al, Ni, W, Pt, Au, TiO₂, Ru, Rh or a combination thereof.

5. The method of claim 1, wherein extending the first probe needle includes:
extending the first probe needle that has:
a ratio of first width of the first crystalline layer over second width of the second crystalline layer that is in a range of about 0.6 to about 1.5.

6. The method of claim 1, wherein extending the first probe needle includes:
extending the first probe needle that has:
a third crystalline layer extending from the first end to the second end, the third crystalline layer and the first crystalline layer having a same first material, the second crystalline layer being positioned between the first crystalline layer and the third crystalline layer; and
a fourth crystalline layer extending from the first end to the second end, the fourth crystalline layer and the second crystalline layer having a same second material different than the first material, the third crystalline layer being positioned between the second crystalline layer and the fourth crystalline layer.

7. The method of claim 1, wherein extending the first probe needle includes:
extending the first probe needle that has the first crystalline layer and the second crystalline layer arranged as concentric rectangular rings.

8. The method of claim 1, wherein extending the first probe needle includes:
extending the first probe needle that has the first crystalline layer and the second crystalline layer arranged as concentric cylindrical rings.

9. A method comprising:
forming a first crystalline layer on a substrate, the first crystalline layer including a first material;
forming a first adhesion layer on the first crystalline layer, the first adhesion layer including a third material that is different than the first material;
forming a second crystalline layer on the first adhesion layer, the second crystalline layer including a second material that is different than the first material and the third material;
singulating a first probe needle structure by dicing the second crystalline layer, the first adhesion layer, the first crystalline layer and the substrate;
forming a second probe needle structure by removing a substrate portion of the first probe needle structure; and
forming a probe needle by forming a resin layer on the second probe needle structure.

10. The method of claim 9, wherein forming the first crystalline layer includes:
forming a first seed layer on the substrate; and
forming the first crystalline layer having first crystalline structure on the first seed layer by a first deposition process including a first precursor of the first material.

11. The method of claim 10, wherein forming the second crystalline layer includes:
forming the second crystalline layer having second crystalline structure on the first adhesion layer by a second deposition process including a second precursor of the second material, the first material having hardness exceeding that of the second material.

12. The method of claim 10, wherein forming the second crystalline layer includes:
forming the second crystalline layer having second crystalline structure on the first adhesion layer by a second deposition process including a second precursor of the second material, the first material having electrical resistivity exceeding that of the second material.

13. The method of claim 10, wherein forming the second crystalline layer includes:
forming the second crystalline layer having second crystalline structure on the first adhesion layer by a second deposition process including a second precursor of the second material, ratio of first thickness of the first material over second thickness of the second material being in a range of about 0.6 to about 1.5.

14. The method of claim 10, further comprising, prior to dicing:
forming a second adhesion layer on the second crystalline layer;
forming a third crystalline layer on the second adhesion layer, the third crystalline layer including the first material;
forming a third adhesion layer on the third crystalline layer; and
forming a fourth crystalline layer on the third adhesion layer, the fourth crystalline layer including the second material.

15. The method of claim 14, wherein:
forming the first crystalline layer includes forming the first crystalline layer having the first material that has hardness exceeding about 4.5 Mohs; and
forming the second crystalline layer includes forming the second crystalline layer having the second material that has electrical resistivity that does not exceed about 5×10E-6 ohm-centimeters.

16. A structure, comprising:
a first surface that, in operation, is in electrical contact with a probe card of a test apparatus;
a second surface that, in operation, is in electrical contact with an electrical connection structure of an integrated circuit (IC) die;
a first crystalline layer that extends continuously from the first surface to the second surface, the first crystalline layer having a first material, a first hardness and first electrical resistivity; and
a second crystalline layer that is adjacent the first crystalline layer and extends continuously from the first surface to the second surface, the second crystalline layer having a second material, a second hardness and a second electrical resistivity, the second material being different than the first material.

17. The structure of claim 16, wherein the first hardness exceeds the second hardness and the first electrical resistivity exceeds the second electrical resistivity.

18. The structure of claim 16, further comprising:
a first adhesion layer that extends continuously from the first surface to the second surface, the first adhesion layer being between the first crystalline layer and the second crystalline layer and including a third material that is different than the first material and different than the second material.

19. The structure of claim 18, further comprising:
a third crystalline layer that extends continuously from the first surface to the second surface, the third crystalline layer having the first material;
a second adhesion layer between the third crystalline layer and the second crystalline layer;
a fourth crystalline layer that extends continuously from the first surface to the second surface, the fourth crystalline layer having the second material; and
a third adhesion layer between the fourth crystalline layer and the third crystalline layer.

20. The structure of claim 19, wherein the first crystalline layer, the second crystalline layer, the third crystalline layer and the fourth crystalline layer are arranged as concentric rings.
